(19) United States
(12) Patent Application Publication
(10) Pub. No.: US 2022/0318456 A1
(43) Pub. Date: Oct. 6, 2022

(54) SIMULATION METHOD BASED ON THREE-DIMENSIONAL CONTOUR, STORAGE MEDIUM, COMPUTER EQUIPMENT

(71) Applicant: SHENZHEN ANTU AUTONOMOUS DRIVING TECHNOLOGIES LTD., SHENZHEN (CN)

(72) Inventor: JIANXIONG XIAO, SHENZHEN (CN)

(21) Appl. No.: 17/708,008

(22) Filed: Mar. 30, 2022

(30) Foreign Application Priority Data
Mar. 30, 2021 (CN) 2021103436510

(51) Int. Cl. G06F 30/20; G06T 17/00; G06T 11/40; G06T 11/00

(52) U.S. Cl. CPC G06F 30/20; G06T 17/00; G06T 11/40; G06T 11/001

(57) ABSTRACT

A simulation method based on three-dimensional contour for an autonomous driving vehicle is provided. The simulation method includes steps of: obtaining a path ID and obtaining image data, and point cloud data according to the path ID, the path ID containing an image data path ID, and a point cloud data path ID; rendering a two-dimensional contour of each of a plurality of objects in the image data according to the image data to obtain a plurality of two-dimensional contours; rendering a plurality of three-dimensional contours according to the plurality of two-dimensional contours and the point cloud data; and performing simulation according to the plurality of the three-dimensional contours. A computer equipment and a storage medium are also provided.

### CROSS REFERENCE TO RELATED APPLICATION

This non-provisional patent application claims priority under 35 U.S.C. § 119 from Chinese Patent Application No. 202110343651.0 filed on Mar. 30, 2021, the entire content of which is incorporated herein by reference.

### TECHNICAL FIELD

The disclosure relates to the field of autonomous driving technology, and in particular to a simulation method based on three-dimensional contour, a storage medium and a computer equipment.

### BACKGROUND

Autonomous driving vehicles have become a new development trend of current vehicles, and corresponding simulation technologies for the autonomous driving vehicles is also increasingly put in an important position. Some existing simulation technologies for the autonomous driving vehicles are performed based on various obstacles and other objects provided in the simulation scene, and it often requires a large amount of computation to process the various data provided by the simulation scene, and will perform a lot of redundant operations. Some other existing simulation technologies simulation are performed based on 2D contour can only provide data in plane dimension and cannot solve a situation of occurring emergency events in blind spot.

Therefore, there is a room for obtaining multi-dimensional environmental data while reducing the amount of computation in the simulation process of an autonomous vehicle.

### SUMMARY

The disclosure provides a simulation method, storage medium, and computer equipment based on three-dimensional contours, which are capable of confirming the obstacle situation by constructing the three-dimensional contours of an object, so as to save computing resources and obtain the simultaneous acquisition during the automatic driving vehicle system performs simulations.

A first aspect of the disclosure provides a simulation method based on three-dimensional contours, the simulation method based on three-dimensional contours includes steps of: obtaining a path ID, and obtaining image data and point cloud data according to the path ID, the path ID containing an image data path ID, and a point cloud data path ID; rendering a two-dimensional contour of each of a plurality of objects in the image data according to the image data to obtain a plurality of two-dimensional contours; rendering a plurality of three-dimensional contours according to the plurality of two-dimensional contours and the point cloud data; and performing simulation according to the plurality of the three-dimensional contours.

A second aspect of the disclosure provides a computer equipment, the computer equipment comprises: a memory configured to store program instructions and a processor configured to execute the program instructions to enable the computer equipment to perform the simulation method based on three-dimensional contours, the simulation method based on three-dimensional contours includes steps of: obtaining a path ID, and obtaining image data and point cloud data according to the path ID, the path ID containing an image data path ID, and a point cloud data path ID; rendering a two-dimensional contour of each of a plurality of objects in the image data according to the image data to obtain a plurality of two-dimensional contours; rendering a plurality of three-dimensional contours according to the plurality of two-dimensional contours and the point cloud data; and performing simulation according to the plurality of the three-dimensional contours.

A third aspect of the disclosure provides a storage medium. The storage medium stores program instructions executed by a processor to perform a simulation method based on three-dimensional contour, the simulation method based on three-dimensional contour includes steps of: obtaining a path ID, and obtaining image data and point cloud data according to the path ID, the path ID containing an image data path ID, and a point cloud data path ID; rendering a two-dimensional contour of each of a plurality of objects in the image data according to the image data to obtain a plurality of two-dimensional contours; rendering a plurality of three-dimensional contours according to the plurality of two-dimensional contours and the point cloud data; and performing simulation according to the plurality of the three-dimensional contours.

As describe above, the simulation method based on the three-dimensional contours does not need to consume a lot of energy to obtain a very good-looking and real picture, which reduces the difficulty of image processing, saves a lot of manpower and computing resources, and thus obtains an ideal simulation effect. At the same time, the simulation method based on the three-dimensional contours can provide more dimensional data to the autonomous vehicle system, ensuring that the autonomous vehicle system can obtain accurate environment and obstacle data, and achieve accurate planning of the driving path.

### BRIEF DESCRIPTION OF THE DRAWINGS

In order to illustrate the technical solution in the embodiments of the disclosure or the prior art more clearly, a brief description of drawings required in the embodiments or the prior art is given below. Obviously, the drawings described below are only some of the embodiments of the disclosure. For ordinary technicians in this field, other drawings can be obtained according to the structures shown in these drawings without any creative effort.

FIG. 1 illustrates a flow diagram of a simulation method based on three-dimensional contours in accordance with an embodiment.

FIG. 2 illustrates a schematic diagram of two-dimensional contours in accordance with an embodiment.

FIG. 3 illustrates a sub-flow diagram of the simulation method based on three-dimensional contours in accordance with a first embodiment.

FIG. 4 illustrates a sub flow diagram of the simulation method based on three-dimensional contours in accordance with a second embodiment.

FIG. 5 illustrates a sub-flow diagram of the simulation method based on three-dimensional contours in accordance with a third embodiment

FIG. 6 illustrates a sub-flow diagram of the simulation method based on three-dimensional contours in accordance with a third embodiment

FIG. 7 illustrates a schematic diagram of a computer equipment in accordance with an embodiment.

### DETAILED DESCRIPTION OF THE EMBODIMENTS

In order to make purpose, technical solution and advanlabeles of the disclosure more clearly, the disclosure is further described in detail in combination with drawings and embodiments. It is understood that the specific embodiments described herein are used only to explain the disclosure and are not used to define it. On the basis of the embodiments in the disclosure, all other embodiments obtained by ordinary technicians in this field without any creative effort are covered by protection of the disclosure.

Terms “first”, “second”, “third”, “fourth”, if any, in specification, claims and drawings of this application are used to distinguish similar objects and need not be used to describe any particular order or sequence of priorities. It should be understood that data are interchangeable when appropriate, in other words, the embodiments described can be implemented in order other than what is illustrated or described here. In addition, terms “include” and “have” and any variation of them, can encompass other things. For example, processes, methods, systems, products, or equipment that comprise a series of steps or units need not be limited to those clearly listed, but may include other steps or units that are not clearly listed or are inherent to these processes, methods, systems, products, or equipment.

It is to be noted that description refers to “first”, “second”, etc. in the disclosure are for descriptive purpose only and neither be construed or implied relative importance nor indicated as implying number of technical features. Thus, feature defined as “first” or “second” can explicitly or implicitly include one or more features. In addition, technical solutions between embodiments may be integrated, but only on the basis that they can be implemented by ordinary technicians in this field. When the combination of technical solutions is contradictory or impossible to be realized, such combination of technical solutions shall be deemed to be non-existent and not within the scope of protection required by the disclosure.

Referring to FIG. 1 and FIG. 5, FIG. 1 illustrates a flow diagram of a control method for an autonomous driving vehicle in accordance with an embodiment, FIG. 5 illustrates a schematic diagram of a control method for an autonomous driving vehicle in accordance with the embodiment. The control method for autonomous driving vehicle includes but is not limited to applied to cars, motorcycles, trucks, sport utility vehicles, recreational vehicles, aircraft and other transportation equipment to control transportation equipment. In this embodiment, when the transportation equipment stops at a certain location and waits for the target to be connected, waiting time of the transportation equipment has exceeded predetermined time, or the transportation equipment cannot continue to park at current location, the control method is used to control the transportation equipment to process in time.

refer to FIG. 1, a flowchart of a simulation method based on three-dimensional contours is illustrated. The simulation method based on three-dimensional contour includes the following steps.

In step S101, a path identity (ID), image data and point cloud data are obtained, and the image data and point cloud data are obtained according to the path ID. The path ID includes an image data path ID, and a point cloud data path ID. An autonomous vehicle system can find the specified image data through the image data path ID, and can find the specified point cloud data through the point cloud data path ID. In detail, the image data path ID includes storage addresses of the image data and names of the image data, for example, “D:\first simulation data\image data\first image.jpg”. The point cloud data path ID includes storage addresses of the point cloud data, and names of the point cloud data. For example “D:\first simulation data\point cloud data\first point cloud.pcd”.

The image data is acquired by a camera or a video camera. The image data is generally configured to acquire short-range targets, perceive features appearing long-range, and detect traffic detection. The point cloud data is acquired by radar devices, such as lidar, millimeter-wave radar, and ultrasonic radar. The point cloud data is generally configured to map 3D environment, and detecting objects.

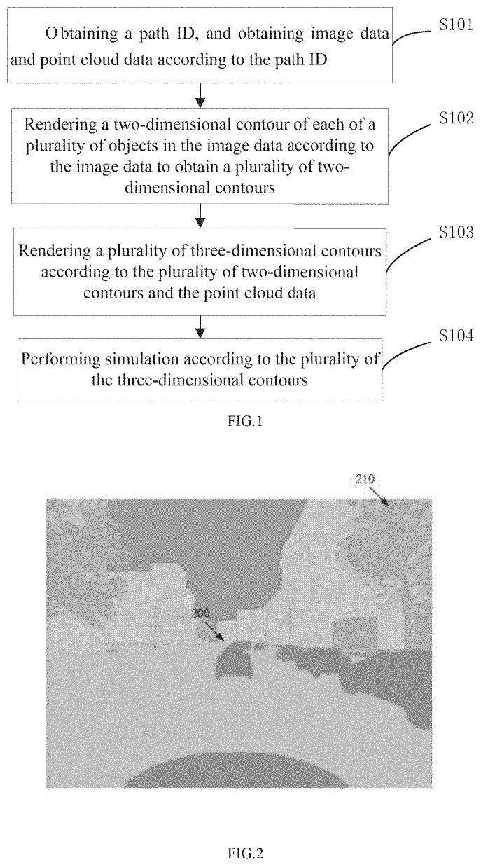

In step S102, a two-dimensional contour of each of a plurality of objects in the image data is rendered according to the image data to obtain a plurality of two-dimensional contours. Each two-dimensional contour presents a shape of an object in a 2D image, and only has a size and a color. As illustrated in FIG. 2, the contours of the obstacle vehicle 200 and the tree 210 only show shapes of the obstacle vehicle 200 and the tree 210 without other information. How to perform the step of acquiring the two-dimensional contour will described in the following steps of S1021-S1025.

In step S103, a plurality of three-dimensional contours are according to rendered according to the plurality of two-dimensional contours and the point cloud data. Each three-dimensional contour presents a three-dimensional object, and each three-dimensional contour is formed by adding spatial data to the corresponding two-dimensional contour, and has a size and a color without other information. How to perform the step of acquiring the three-dimensional contour will described in the following steps of S1031-S1033.

In step S104, simulation is performed according to the plurality of three-dimensional contours. In detail, three-dimensional contours are shapes of the three-dimensional object but not appearances of the objects. Simulation software recognizes obstacles to what objects or types of the objects via three-dimensional contours, so as to achieve near-perfect graphics perception and radar perception. It does not need to run deep learning or other models, and directly obtain part of the perception results.

Referring to FIG. 3, a flowchart of sub-steps of step S102 is illustrated in accordance with a first embodiment. The step S102. includes the following steps.

In step S1021, a category of each object in the image data is identified to obtain a plurality of categories by a preset image recognition algorithm. The image recognition algorithms identify all objects, such as vehicles and trees, in the image data, The image recognition algorithms includes the Brief algorithm, the BRISK algorithm, the ORB algorithm or the FREAK algorithm and so on

In step S1022, first labels are is added to a plurality of objects according to a plurality of categories to obtain a plurality of first labels. Each first label is a label for distinguishing what class each two-dimensional object is. For example, one first label indicating a vehicle is added to the object identified as a vehicle, while another first label indicating a tree identified as a tree is added to the object.

In the step S1023, a plurality of contours of a plurality of objects are acquired. In detail, how to acquire the plurality of contours will described in the following steps of S10231-S10233.

In the step S1024, a color corresponding to the first label of each object is obtained. In detail, the color corresponding to the first label of each object can be random matched by the automatic driving system. In some other embodiments, the color corresponding to the first label of each object can also be pre-set.

In the step S1025, the corresponding colors are filled to the plurality of contours and regions surrounded by the plurality of contours to obtain a plurality of two-dimensional contours.

In this embodiment, the two-dimensional data of the road conditions encountered by the autonomous driving vehicle in the simulation scene is obtained by obtaining the two-dimensional contour, which is similar to two-dimensional data viewed by the human. And only the contours of the two-dimensional data are needed and unnecessary details data of the objects are reduce, For example, the specific content of the bumper, license plate and so on on the vehicle are not contained in the two-dimensional data. It greatly reduces the amount of computation for the autonomous vehicle to process actual environmental data, and improves the speed at which the autonomous vehicle system processes environmental data.

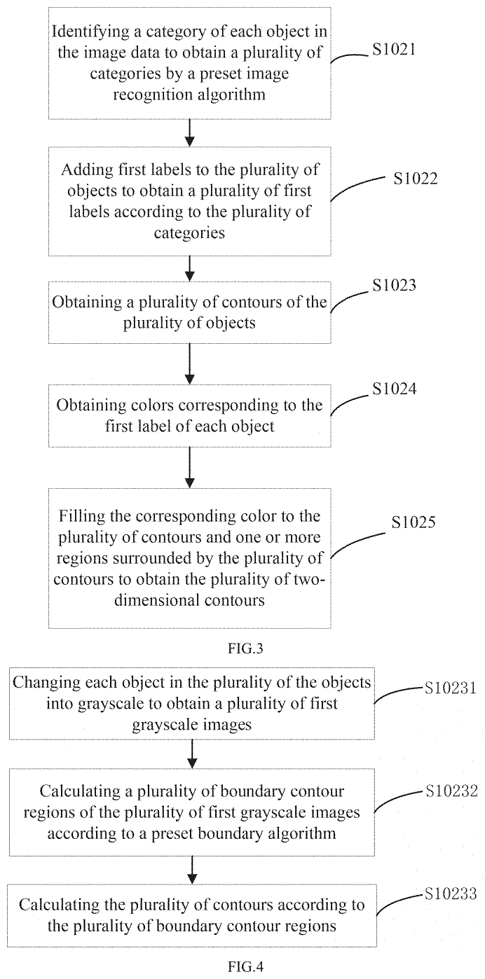

Referring to FIG. 4, a flowchart of sub-steps of the step S1023 is illustrated in accordance with an embodiment. How to acquire the plurality of contours of a plurality of objects will be described in the following steps of S10231-S10233.

In the step S10231, each object in the plurality of the objects is changed into grayscale to obtain a plurality of first grayscale images. Each first grayscale image is an image in grayscale without color. In detail, the image is binarized, and then the object in the image data is refined through edge response to obtain a single-pixel edge image. Then, the image data is further processed by a non-maximum suppression method, also called a local maximum search algorithm. The roof bands in gradient magnitude images can be very efficiently refined by non-maxima suppression, so that only the points with the largest local variation are retained.

In the step S10232, a plurality of boundary contour regions of a plurality of first grayscale images are calculated according to a preset boundary algorithm. The boundary contour area is a part of the boundary of the object. In detail, a binarization of the basis of the pre-processed first grayscale image is performed based on a hysteresis threshold. The hysteresis threshold can ensure that the final contour image is continuous by using a recursive tracking algorithm. The binary process is regularly associated with standard contours, such as artificially drawn contours in an image database. In some other embodiments, another general method for obtaining the boundary contour area includes segmenting the images, and then the boundary of the segmented area is directly used as the boundary contour area.

In the step S10233, a plurality of contours are calculated according to the plurality of boundary contour regions. In detail, the plurality of contours are calculated from the plurality of boundary contour regions according to the principle of maximum area.

In this embodiment, an image with a plurality of colors is converted into a image with only grayscale, which reduces the amount of calculation for the automatic driving vehicle system to process the details in the picture, and improves the calculation and recognition efficiency of the automatic driving vehicle system.

Referring to FIG. 5, a flowchart of sub-steps of step S103 is illustrated in accordance with a first embodiment. How to render a plurality of three-dimensional contours according to a plurality of two-dimensional contours and point cloud data will be described in the following steps of S1031-S1033.

In the step S1031, a second label to each of the plurality of objects is added according to the point cloud data to obtain a plurality of second labels. How to acquired a plurality of second labels will described of steps S10311-S10312.

In the step S1032, the plurality of the first labels and the plurality of the second labels are matched to generate a plurality of pairs of three-dimensional information. In detail, a first label indicating a vehicle and a second label indicating a vehicle are matched as a pair of three-dimensional information. The plurality of first labels in the image data and the plurality of second labels in the point cloud data are matched into the plurality of three-dimensional information pairs.

In the step S1033, a plurality of three-dimensional contours are rendered according to the information contained in the plurality of three-dimensional information pairs. In detail, the three-dimensional information in the three-dimensional data is supplemented into the two-dimensional contour.

In this embodiment, the three-dimensional contours are capable of providing the autonomous vehicle with more spatial information of obstacles. Comparing with the existing two-dimensional contours, the three-dimensional contours can provide more effective information. For example, the situation of a traffic light being blocked by a large truck in front, the situation of someone suddenly running out from the front of a large truck parked on the side of the road, cannot be solved by the data provided by the two-dimensional contour. The three-dimensional contour can provide spatial data about the truck as a whole, so that the autonomous vehicle system can calculate the spatial relationship between the traffic lights and the obstacle truck and the autonomous vehicle itself, and carry out the next trajectory planning according to the spatial relationship. In the same way, although two-dimensional contours can also detect ghost probes, the lack of distance dimension information makes the autonomous vehicle unable to make correct decisions. The three-dimensional contour can accurately provide distance information, and the autonomous vehicle can make correct decisions.

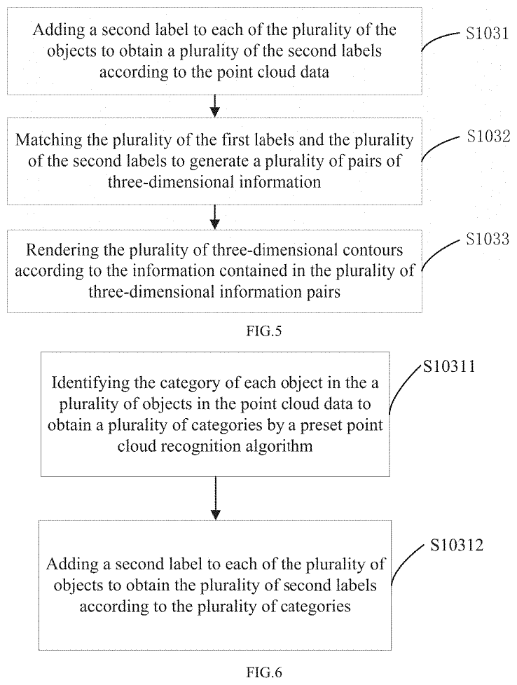

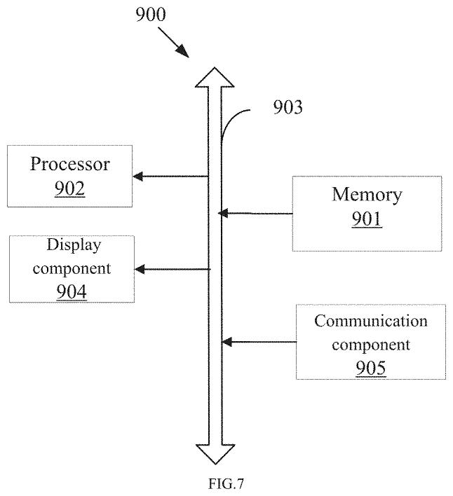

Referring to FIG. 6, a sub-flowchart of the step S1031 is illustrated in accordance with a first embodiment.

In the step S1031, a second label is added to each of the plurality of objects according to the point cloud data to obtain a plurality of second labels. The step S1031 further includes the following steps S10311-S10312.

In the step S10311, the category of each object in the a plurality of objects in the point cloud data is identified to obtain a plurality of categories according to a preset point cloud recognition algorithm.

In the step S10312, a second label is added to each of the plurality of objects according to the plurality of categories to obtain a plurality of second labels. The second label is a label indicating a specific category of a point cloud object. In detail, the second label is added to each identified object of the point cloud data.

A simulation method based on three-dimensional contours in accordance with a second embodiment is further provided. The difference between the simulation method based on three-dimensional contours of the second embodiment and the simulation method based on three-dimensional contours provided of the first embodiment is that the simulation method based on three-dimensional contours of the second embodiment further includes step of: evaluating a capability of a sensor generating information about three-dimensional contours according to the three-dimensional contours. Specifically, when a 79 GHz millimeter-wave radar is newly installed on the autonomous vehicle to detecting obstacles 100 meters in front of the autonomous vehicle, it is detected that whether the 79 GHz millimeter-wave radar is suitable for detecting obstacles 100 meters in front of the autonomous vehicle. In detail, the data of the 79 GHz millimeter-wave radar can be added to the autonomous vehicle system first, and the performance of the 79 GHz millimeter-wave radar in the simulation scenario can be tested.

In this embodiment, the simulation scenario is used to test the new sensor, which saves the hardware cost and time cost of the test.

A simulation method based on three-dimensional contours in accordance with a third embodiment is further provided. The difference between the simulation method based on three-dimensional contours of accordance with a third embodiment and the simulation method based on three-dimensional contours of the first embodiment is that, the simulation method based on three-dimensional contours of the third embodiment further includes step of: adjusting parameters of of a sensor generating information about three-dimensional contours according to the three-dimensional contours. In detail, when a 79 GHz millimeter-wave radar is installed on the autonomous vehicle, it is checked whether the scanning parameters currently set by the 79 GHz millimeter-wave radar can clearly detect obstacles 100 meters in front of the autonomous vehicle. Further more, the 79 GHz millimeter-wave radar is preset scanning parameters and the parameters of the 79 GHz millimeter-wave radar is adjusted according to the test results returned by the simulation system under the scense.

In this embodiment, the parameters of the sensor in different scenarios are debugged by simulation scenarios, which saves the hardware cost and time cost of testing.

The disclosure also provides a storage medium storing program instructions of any one of simulation method based on three-dimensional contours that can be loaded and executed by a processor.

If the simulation method based on three-dimensional contours is implemented in the form of software functional units and sold or used as an independent product, it can be stored in a computer-readable storage medium. Based on this understanding, the technical solutions of the present application can be embodied in the form of software products in essence, or the parts that contribute to the prior art, or all or part of the technical solutions, and the computer software products are stored in a storage medium, including several instructions to cause a computer device (which may be a personal computer, a server, or a network device, etc.) to execute all or part of the steps of the methods in the various embodiments of the present application. The aforementioned storage medium includes: U disk, mobile hard disk, Read-Only Memory (ROM, Read-Only Memory), Random Access Memory (RAM, Random Access Memory), magnetic disk or optical disk and other media that can store program instructions. Since the storage medium adopts all the technical solutions of the above-mentioned embodiments, it has at least all the beneficial effects brought by the technical solutions of the above-mentioned embodiments, which will not be repeated here.

The present invention also provides a computer device, the computer device includes: a memory 901 for storing program instructions of a simulation method based on three-dimensional contours; a processor 902 for executing the program instructions to enable the computer device to implement any one of the above simulation method based on three-dimensional contours.

Referring to FIG. 7, a schematic diagram of the internal structure of the computer device 900 is illustrated according to the first embodiment.

The memory 901 includes at least one type of readable storage medium, including flash memory, hard disk, multimedia card, card-type memory (eg, SD or DX memory, etc.), magnetic memory, magnetic disk, optical disk, and the like. The memory 901 may in some embodiments be an internal storage unit of the computer device 900, such as a hard disk of the computer device 900. The memory 901 may also be an external storage device of the computer device 900 in other embodiments, such as a pluggable hard disk, a smart memory card (Smart Media Card, SMC), a secure digital card (Secure Digital, SD card) equipped on the computer device 900), Flash Card, etc. Further, the memory 901 may also include both an internal storage unit of the computer device 900 and an external storage device. The memory 901 can not only be used to store application software installed in the computer device 900 and various types of data, such as simulation methods based on three-dimensional contours, etc., but also can be used to temporarily store data that has been output or will be output. For example, three-dimensional contour data, etc.

The processor 902 may be a central processing unit (Central Processing Unit, CPU), a controller, a micro controller, a microprocessor or other data processing chips in some embodiments, and is used to execute program instructions or process data stored in the memory 901. Specifically, the processor 902 executes the program instructions of the simulation method based on three-dimensional contours to control the computer device 900 to implement the simulation method based on three-dimensional contours. The above embodiments have described the detailed process of the processor 902 in the computer device 900 executing the program instructions of the simulation method based on three-dimensional contours to control the computer device 900 to implement the simulation method based on three-dimensional contours, and details are not repeated here.

Further, the bus 903 may be a peripheral component interconnect (PCI for short) or an extended industry standard architecture (EISA for short) or the like. The bus can be divided into address bus, data bus, control bus and so on. For ease of presentation, only one thick line is used in FIG. 7, but it does not mean that there is only one bus or one type of bus.

Further, computer device 900 may also include display component 904. The display component 904 may be an LED (Light Emitting Diode, light-emitting diode) display, a liquid crystal display, a touch-sensitive liquid crystal display, an OLED (Organic Light-Emitting Diode, organic light-emitting diode) touch device, and the like. The display component 904 may also be appropriately referred to as a display device or a display unit for displaying information processed in the computer device 900 and for displaying a visual user interface.

Further, the computer device 900 may also include a communication component 905, and the communication component 905 may optionally include a wired communication component and/or a wireless communication component (such as a WI-FI communication component, a Bluetooth communication component, etc.), which are generally used in computer equipment A communication connection is established between 900 and other computer devices.

FIG. 7 only shows a computer device 900 having components 901-905 and program instructions for implementing the simulation method based on three-dimensional contours. Those skilled in the art can understand that the structure shown in FIG. 7. By definition, fewer or more components than shown may be included, or some components may be combined, or a different arrangement of components.

In the above-mentioned embodiments, it may be implemented in whole or in part by software, hardware, firmware or any combination thereof. When implemented in software, it can be implemented in whole or in part in the form of a computer program product.

Specifically, the simulation method based on three-dimensional contours includes one or more program instructions. When the program instructions are loaded and executed on the computer device 900, the procedures or functions of the embodiments of the present invention are generated in whole or in part. The computer device 900 may be a general purpose computer, a special purpose computer, a computer network, or other programmable apparatus. The program instructions may be stored in a computer-readable storage medium or transmitted from one computer-readable storage medium to another computer-readable storage medium, for example, the program instructions may be transmitted from a website site, computer, server or data center via wired (eg coaxial cable, fiber optic, digital subscriber line (DSL)) or wireless (eg infrared, wireless, microwave, etc.) to another website site, computer, server or data center. The computer-readable storage medium can be any available medium that can be stored by a computer, or a data storage device such as a server, data center, etc., which includes one or more available media integrated. The available media may be magnetic media (eg, floppy disks, hard disks, magnetic tapes), optical media (eg, DVD), or semiconductor media (eg, Solid State Disk (SSD)), among others.

Those skilled in the art can clearly understand that, for the convenience and brevity of description, the specific working process of the system, device and unit described above can refer to the corresponding process in the above method embodiments, and details are not repeated here.

In the several embodiments provided in this application, it should be understood that the disclosed system, apparatus and method may be implemented in other manners. For example, the above-described simulation method based on three-dimensional contours embodiment is only illustrative. For example, the division of the unit is only a logical function division. In actual implementation, there may be other division methods, such as a plurality of units or Components may be combined or may be integrated into another system, or some features may be omitted, or not implemented. On the other hand, the shown or discussed mutual coupling or direct coupling or communication connection may be through some interfaces, indirect coupling or communication connection of devices or units, and may be in electrical, mechanical or other forms.

The unit described as a detached part may or may not be physically detached, the parts shown as unit may or may not be physically unit, that is, it may be located in one place, or it may be distributed across a plurality of network units. Some or all of the units can be selected according to actual demand to achieve the purpose of this embodiment scheme.

In addition, the functional units in each embodiment of this disclosure may be integrated in a single processing unit, or may exist separately, or two or more units may be integrated in a single unit. The integrated units mentioned above can be realized in the form of hardware or software functional units.

It should be noted that the embodiments number of this disclosure above is for description only and do not represent the advantages or disadvantages of embodiments. And in this disclosure, the term “including”, “include” or any other variants is intended to cover a non-exclusive contain. So that the process, the devices, the items, or the methods includes a series of elements not only include those elements, but also include other elements not clearly listed, or also include the inherent elements of this process, devices, items, or methods. In the absence of further limitations, the elements limited by the sentence “including a . . . ” do not preclude the existence of other similar elements in the process, devices, items, or methods that include the elements.

The above are only the preferred embodiments of this disclosure and do not therefore limit the patent scope of this disclosure. And equivalent structure or equivalent process transformation made by the specification and the drawings of this disclosure, either directly or indirectly applied in other related technical fields, shall be similarly included in the patent protection scope of this disclosure.

1. A simulation method based on three-dimensional contour for an autonomous driving vehicle, comprising:
obtaining a path ID, and obtaining image data and point cloud data according to the path ID, the path ID containing an image data path ID, and a point cloud data path ID;
rendering a two-dimensional contour of each of a plurality of objects in the image data according to the image data to obtain a plurality of two-dimensional contours;
rendering a plurality of three-dimensional contours according to the plurality of two-dimensional contours and the point cloud data; and
performing simulation according to the plurality of the three-dimensional contours.

2. The simulation method based on three-dimensional contours according to claim 1, wherein the image data path ID includes storage addresses of the image data and names of the image data; the point cloud data path ID includes storage addresses and names of the point cloud data.

3. The simulation method based on a three-dimensional contour according to claim 1, wherein rendering a two-dimensional contour of each of a plurality of objects in the image data according to the image data to obtain a plurality of two-dimensional contours comprising:
identifying a category of each object in the image data to obtain a plurality of categories by a preset image recognition algorithm;
adding first labels to the plurality of objects to obtain a plurality of first labels according to the plurality of categories;
obtaining a plurality of contours of the plurality of objects;
obtaining colors corresponding to the first label of each object; and
filling the corresponding color to the plurality of contours and one or more regions surrounded by the plurality of contours to obtain the plurality of two-dimensional contours.

4. The simulation method based on three-dimensional contours according to claim 3, wherein obtaining a plurality of contours of the plurality of objects comprises:
changing each object in the plurality of the objects into grayscale to obtain a plurality of first grayscale images;
calculating a plurality of boundary contour regions of the plurality of first grayscale images according to a preset boundary algorithm; and
calculating the plurality of contours according to the plurality of boundary contour regions.

5. The simulation method based on three-dimensional contours according to claim 3, wherein rendering a plurality of three-dimensional contours according to the plurality of two-dimensional contours and the point cloud data comprising:
adding a second label to each of the plurality of the objects to obtain a plurality of the second labels according to the point cloud data;
matching the plurality of the first labels and the plurality of the second labels to generate a plurality of pairs of three-dimensional information; and
rendering the plurality of three-dimensional contours according to the information contained in the plurality of three-dimensional information pairs.

6. The simulation method based on three-dimensional contours according to claim 5, wherein adding a second label to each of the plurality of the objects to obtain a plurality of the second labels according to the point cloud data comprises:
identifying the category of each object in the a plurality of objects in the point cloud data to obtain a plurality of categories by a preset point cloud recognition algorithm; and
adding a second label to each of the plurality of objects to obtain the plurality of second labels according to the plurality of categories.

7. The simulation method based on three-dimensional contours according to claim 1, further comprising: evaluating a capability of a sensor generating information about three-dimensional contours according to the three-dimensional contours.

8. The simulation method based on three-dimensional contours according to claim 1, further comprising: adjusting parameters of a sensor generating information about three-dimensional contours according to the three-dimensional contours.

9. A computer equipment, the computer equipment comprising:
one or more memories configured to store program instructions; and
one or more processor, configured to execute the program instructions to enable the computer equipment to perform a simulation method based on three-dimensional contour, the simulation method based on three-dimensional contour comprising:
obtaining a path ID, and obtaining image data and point cloud data according to the path ID, the path ID containing an image data path ID, and a point cloud data path ID;
rendering a two-dimensional contour of each of a plurality of objects in the image data according to the image data to obtain a plurality of two-dimensional contours;
rendering a plurality of three-dimensional contours according to the plurality of two-dimensional contours and the point cloud data; and
performing simulation according to the plurality of three-dimensional profiles.

10. The computer equipment according to claim 9, wherein the image data path ID includes storage addresses of the image data and names of the image data; the point cloud data path ID includes storage addresses and names of the point cloud data.

11. The computer equipment according to claim 9, wherein rendering a two-dimensional contour of each of a plurality of objects in the image data according to the image data to obtain a plurality of two-dimensional contours comprising:
identify a category of each object in the image data to obtain a plurality of categories by a preset image recognition algorithm;
adding first labels to the plurality of objects to obtain a plurality of first labels according to the plurality of categories;
obtaining a plurality of contours of the plurality of objects;
obtaining colors corresponding to the first label of each object; and
filling the corresponding color to the plurality of contours and one or more regions surrounded by the plurality of contours to obtain the plurality of two-dimensional contours.

12. The computer equipment according to claim 11, wherein obtaining a plurality of contours of the plurality of objects comprises:
changing each object in the plurality of the objects into grayscale to obtain a plurality of first grayscale images;
calculating a plurality of boundary contour regions of the plurality of first grayscale images according to a preset boundary algorithm; and
calculating the plurality of contours according to the plurality of boundary contour regions.

13. The computer equipment according to claim 11, wherein rendering a plurality of three-dimensional contours according to the plurality of two-dimensional contours and the point cloud data comprising:
adding a second label to each of the plurality of the objects to obtain a plurality of the second labels according to the point cloud data;
matching the plurality of the first labels and the plurality of the second labels into a plurality of pairs of three-dimensional information; and
rendering the plurality of three-dimensional contours according to the information contained in the plurality of three-dimensional information pairs.

14. The computer equipment according to claim 13, wherein adding a second label to each of the plurality of the objects to obtain a plurality of the second labels according to the point cloud data include:
identifying the category of each object in the a plurality of objects in the point cloud data to obtain a plurality of categories by a preset point cloud recognition algorithm; and
adding a second label to each of the plurality of objects to obtain the plurality of second labels according to the plurality of categories.

15. The computer equipment according to claim 9, wherein simulation method based on three-dimensional contour further comprises: evaluating a capability of a sensor generating information about three-dimensional contours according to the three-dimensional contours.

16. The computer equipment according to claim 9, wherein simulation method based on three-dimensional contour further comprises: adjusting parameters of a sensor generating information about three-dimensional contours according to the three-dimensional contours.

17. A storage medium, the storage medium storing program instructions executed by a processor to perform a simulation method based on three-dimensional contour, the simulation method based on three-dimensional contour comprising:
obtaining a path ID, and obtaining image data and point cloud data according to the path ID, the path ID containing an image data path ID, and a point cloud data path ID;
rendering a two-dimensional contour of each of a plurality of objects in the image data according to the image data to obtain a plurality of two-dimensional contours;
rendering a plurality of three-dimensional contours according to the plurality of two-dimensional contours and the point cloud data; and
performing simulation according to the plurality of three-dimensional profiles.

18. The storage medium according to claim 17, wherein rendering a two-dimensional contour of each of a plurality of objects in the image data according to the image data to obtain a plurality of two-dimensional contours comprising:
identify a category of each object in the image data to obtain a plurality of categories by a preset image recognition algorithm;
adding first labels to the plurality of objects to obtain a plurality of first labels according to the plurality of categories;
obtaining a plurality of contours of the plurality of objects;
obtaining colors corresponding to the first label of each object; and
filling the corresponding color to the plurality of contours and one or more regions surrounded by the plurality of contours to obtain the plurality of two-dimensional contours.

19. The storage medium according to claim 18, wherein obtaining a plurality of contours of the plurality of objects comprises:
changing each object in the plurality of the objects into grayscale to obtain a plurality of first grayscale images;
calculating a plurality of boundary contour regions of the plurality of first grayscale images according to a preset boundary algorithm; and
calculating the plurality of contours according to the plurality of boundary contour regions.

20. The storage medium according to claim 17, wherein rendering a plurality of three-dimensional contours according to the plurality of two-dimensional contours and the point cloud data comprising:
adding a second label to each of the plurality of the objects to obtain a plurality of the second labels according to the point cloud data;
matching the plurality of the first labels and the plurality of the second labels into a plurality of pairs of three-dimensional information; and
rendering the plurality of three-dimensional contours according to the information contained in the plurality of three-dimensional information pairs.
